(19) United States
(12) Patent Application Publication
(10) Pub. No.: US 2026/0054324 A1
(43) Pub. Date: Feb. 26, 2026

(54) SUBSTRATE PROCESSING METHOD AND SUBSTRATE PROCESSING APPARATUS

(71) Applicant: SEMES CO., LTD., Cheonan-si (KR)

(72) Inventors: Seryeyohan CHO, Daejeon (KR); Young Dae CHUNG, Incheon (KR); Tae Shin KIM, Suwon-si (KR)

(73) Assignee: SEMES CO., LTD., Cheonan-si (KR)

(21) Appl. No.: 19/303,613

(22) Filed: Aug. 19, 2025

(30) Foreign Application Priority Data
Aug. 23, 2024 (KR) 10-2024-0113249

(51) Int. Cl. B23K 26/362; B23K 26/06; B23K 26/067; B23K 26/402; B23K 26/70; B23K 103/00; H01L 21/268; H01L 21/306

(52) U.S. Cl. CPC B23K 26/362; B23K 26/0643; B23K 26/067; B23K 26/402; H01L 21/268; H01L 21/30604; B23K 26/704; B23K 2103/56

(57) ABSTRACT

Disclosed is a method of processing a substrate, the method including: a heating operation of irradiating a substrate with a laser generated from a laser source and heating the substrate, in which the heating operation includes: a laser splitting operation of splitting the laser into a plurality of beamlets using an optical modulation unit; and a laser irradiating operation of irradiating the substrate with the plurality of beamlets, and the plurality of beamlets is emitted so as not to overlap or be connected to one another.

### CROSS-REFERENCE TO RELATED APPLICATION

This application claims priority to and the benefit of Korean Patent Application No. 10-2024-0113249 filed in the Korean Intellectual Property Office on Aug. 23, 2024, the entire contents of which are incorporated herein by reference.

### TECHNICAL FIELD

The present invention relates to a substrate processing method and a substrate processing apparatus, and more particularly, to a method and apparatus for processing a substrate by emitting a laser.

### BACKGROUND ART

Various processes, such as photography, etching, ashing, ion implantation, and thin film deposition, are performed on substrates, such as wafers, to manufacture semiconductor devices. Various processing liquids and processing gas are used in each process. In addition, in order to remove the processing liquid used to process the substrate from the substrate, a drying process is performed on the substrate.

Recently, as the line width of semiconductor circuits has become more fine, a method of modulating the laser beam L using light modulation devices, such as digital micro-mirror devices (hereinafter referred to as DMD), to form an irradiation pattern and irradiating substrates, such as masks and wafers, with the irradiation pattern is used.

Meanwhile, light may be irradiated onto the upper surface of the substrate, where the liquid film by the chemical solution is formed, to heat a specific area of the substrate. The entire pattern on the substrate is etched by the chemical solution, but the specific area irradiated with light may be heated to be further etched. The degree of etching depends on the amount of heat transmitted by light per unit time, and since DMD may form various forms of irradiation patterns, etching of the substrate M may be controlled in various forms.

When the substrate M is heated by irradiating the substrate with a light source in the form of a point light source, a temperature gradient occurs in the heating area and a uniform temperature distribution is not formed, but a uniform temperature distribution may be induced by lowering the energy density of the center of the light source by using DMD. However, in this case, there is a problem that an optimized shape needs to be modeled and calculated according to an arbitrary etching shape given for each substrate.

### SUMMARY OF THE INVENTION

The present invention has been made in an effort to provide a substrate processing method and a substrate processing apparatus capable of effectively processing a substrate.

The present invention has also been made in an effort to provide a substrate processing method and a substrate processing apparatus capable of effectively adjusting a line width of a pattern formed on a substrate.

The present invention has also been made in an effort to provide a substrate processing method and a substrate processing apparatus capable of irradiating a substrate with a laser so that a temperature distribution within a specific area of the substrate that needs be to heated becomes uniform.

The present invention has also been made in an effort to provide a substrate processing method and a substrate processing apparatus capable of uniformly heating arbitrary shapes that require heating.

The objectives of the present disclosure are not limited thereto and other objectives not stated herein may be clearly understood by those skilled in the art from the following description.

An exemplary embodiment of the present invention, a method of processing a substrate, the method comprising: a heating operation of irradiating a substrate with a laser generated from a laser source and heating the substrate, wherein the heating operation includes: a laser splitting operation of splitting the laser into a plurality of beamlets using an optical modulation unit; and a laser irradiating operation of irradiating the substrate with the plurality of beamlets, and the plurality of beamlets may be emitted so as not to overlap or be connected to one another.

According to the exemplary embodiment of the present invention, the substrate includes a plurality of irradiation areas that require heating, and the optical modulation unit may splits the laser so that the plurality of beamlets respectively irradiates the plurality of irradiation areas.

According to the exemplary embodiment of the present invention, the irradiation area is divided into a plurality of unit irradiation areas, and the beamlet may heats the entire irradiation area by sequentially irradiating the plurality of unit irradiation areas.

According to the exemplary embodiment of the present invention, when the beamlet heats the unit irradiation area, the unit irradiation area may be heated uniformly.

According to the exemplary embodiment of the present invention, wherein after the beamlet sequentially irradiates the plurality of unit irradiation areas to heat the entire irradiation area, a cumulative heating amount in the entire irradiation area may be uniform.

According to the exemplary embodiment of the present invention, wherein after a first area is heated by irradiating the first area among the plurality of unit irradiation areas with the beamlet, a second area is heated by irradiating the second area among the plurality of unit irradiation areas with the beamlet, and the second area may be an area adjacent to the first area.

According to the exemplary embodiment of the present invention, wherein a horizontal length of the first area is 1/M of a horizontal length of the irradiation area, a vertical length of the first area is 1/N of a vertical length of the irradiation area, and each of M and N may be a natural number of 2 or more.

According to the exemplary embodiment of the present invention, wherein an area of the second area may be the same as an area of the first area.

According to the exemplary embodiment of the present invention, wherein the unit irradiation area may has a rectangular shape.

According to the exemplary embodiment of the present invention, wherein the optical modulation unit is a Digital Micromirror Device (DMD) unit, and the DMD unit includes: micromirror provided rotatably; and a board substrate on which the micromirrors are installed, and the heating operation includes adjusting a direction in which each of the micromirrors reflects the laser, and selectively heating the substrate through switching between an on-state in which the laser is reflected to irradiate the substrate and an off-state, in which the laser may be dumped.

According to the exemplary embodiment of the present invention, the method may further include a processing liquid supplying operation of supplying a processing liquid to the substrate prior to the heating operation.

An exemplary embodiment of the present invention, an apparatus for processing a substrate, the apparatus comprising: a support unit for supporting a substrate; a liquid supply unit for supplying a liquid to the substrate supported by the support unit; a laser irradiation module for irradiating a specific area on the substrate supported by the support unit with a laser; and a controller, wherein the laser irradiation module includes: a laser source for generating a laser; and a Digital Micromirror Device (DMD) unit, which is an optical modulation unit that modulates the laser generated from the laser source, and the DMD unit includes: micromirror provided rotatably; and a board substrate on which the micromirrors are installed, and the controller splits the laser into a plurality of beamlets through the micromirrors may control the plurality of beamlets to respectively irradiate different areas on the substrate.

According to the exemplary embodiment of the present invention, the laser irradiation module further may include a Galvano scanner that changes an irradiation position at which the beamlet split through the DMD unit irradiates the substrate.

According to the exemplary embodiment of the present invention, the substrate includes a plurality of irradiation areas that require heating, and the controller may controls the laser irradiation module so that the plurality of beamlets respectively irradiates the plurality of irradiation areas.

According to the exemplary embodiment of the present invention, the irradiation area is divided into a plurality of unit irradiation areas, and the controller may controls the laser irradiation module so that the beamlet sequentially irradiates the plurality of unit irradiation areas to heat the entire irradiation area.

An exemplary embodiment of the present invention, a method of processing a substrate, the method comprising: an etching operation of etching a substrate, wherein the etching operation of etching the substrate includes: a processing liquid supplying operation of supplying a processing liquid to the substrate; and a heating operation of irradiating the substrate with a laser generated from a laser source and heating the substrate, wherein the heating operation includes: a laser splitting operation of splitting the laser into a plurality of beamlets using a Digital Micromirror Device (DMD) unit including rotatably provided micromirrors; and a laser irradiating operation of irradiating the substrate with the plurality of beamlets, and the substrate includes a plurality of irradiation areas that require heating, and each of the plurality of beamlets may be emitted to correspond to one irradiation area.

According to the exemplary embodiment of the present invention, the irradiation area is divided into a plurality of unit irradiation areas, and the beamlet may heats the entire irradiation area by sequentially irradiating the plurality of unit irradiation areas.

According to the exemplary embodiment of the present invention, when the beamlet heats the unit irradiation area, the unit irradiation area may be heated uniformly.

According to the exemplary embodiment of the present invention, wherein after the beamlet sequentially irradiates the plurality of unit irradiation areas to heat the entire irradiation area, a cumulative heating amount in the entire irradiation area may be uniform.

According to the exemplary embodiment of the present invention, wherein after a first area is heated by irradiating the first area among the plurality of unit irradiation areas with the beamlet, a second area is heated by irradiating the second area among the plurality of unit irradiation areas with the beamlet, and the second area is an area adjacent to the first area, and the first area and the second area may have a rectangular shape.

According to the exemplary embodiment of the present invention, it is possible to effectively process the substrate.

In addition, according to the exemplary embodiment of the present invention, it is possible to effectively etch the substrate.

In addition, according to the exemplary embodiment of the present invention, it is possible to irradiate a substrate with a laser so that the temperature distribution within a specific area of the substrate that needs to be heated becomes uniform.

In addition, according to the exemplary embodiment of the present invention, it is possible to uniformly heat an arbitrary shape that needs to be heated.

Effects of the present disclosure are not limited to those described above and effects not stated above will be clearly understood to those skilled in the art from the specification and the accompanying drawings.

### BRIEF DESCRIPTION OF THE DRAWINGS

FIG. 1 is a top plan view schematically illustrating a substrate processing apparatus according to an exemplary embodiment of the present invention.

FIG. 2 is a diagram schematically illustrating a state of a substrate processed in a liquid processing chamber of FIG. 1.

FIG. 3 is a diagram schematically illustrating an exemplary embodiment of the liquid processing chamber of FIG. 1.

FIG. 4 is a graph illustrating distribution of light output from a laser source.

FIG. 5 is a graph illustrating distribution of light passing through a flat top optical instrument.

FIG. 6 is a diagram schematically illustrating an optical modulation element.

FIG. 7 is a diagram illustrating a state in which a laser beam is output from the optical modulation element.

FIG. 8 is a diagram illustrating a state in which a laser beam output from the optical modulation element is removed from an optical dumper.

FIG. 9 is a diagram for describing a principle in which a laser beam is removed from the optical dumper.

FIG. 10 is a diagram for describing an irradiation pattern of a laser beam output from an optical modulation unit.

FIG. 11 is a view illustrating a state in which an irradiation position change instrument changes an irradiation position of the laser beam.

FIG. 12 is a diagram illustrating a state in which an irradiation position change instrument switches a traveling direction of a laser beam traveling in an oblique direction to a vertical direction.

FIG. 13 is a flowchart illustrating a substrate processing method according to an exemplary embodiment of the present invention.

FIG. 14 is a cross-sectional view illustrating a substrate processing apparatus performing a processing liquid supplying operation according to the exemplary embodiment.

FIGS. 15 to 16 are cross-sectional views illustrating a substrate processing apparatus performing a heating operation according to the exemplary embodiment.

FIG. 17 is a diagram schematically illustrating a configuration of a specific area which is irradiated with a laser beam.

FIGS. 18 to 20 are diagrams illustrating a state in which the specific area of FIG. 17 is irradiated with a laser beam when the laser irradiating operation is performed.

FIG. 21 is a diagram schematically illustrating an exemplary embodiment in which the substrate is irradiated and heated with a laser beam in accordance with an arbitrary etching required shape.

FIG. 22 is a cross-sectional view illustrating the substrate processing apparatus performing a rinse liquid supplying operation according to the exemplary embodiment.

Various features and advantages of the non-limiting exemplary embodiments of the present specification may become apparent upon review of the detailed description in conjunction with the accompanying drawings. The attached drawings are provided for illustrative purposes only and should not be construed to limit the scope of the claims. The accompanying drawings are not considered to be drawn to scale unless explicitly stated. Various dimensions in the drawing may be exaggerated for clarity.

Example embodiments will now be described more fully with reference to the accompanying drawings. Example embodiments are provided so that this disclosure will be thorough and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure. In some example embodiments, well-known processes, well-known device structures, and well-known technologies are not described in detail.

The terminology used herein is for the purpose of describing particular example embodiments only and is not intended to be limiting. As used herein, the singular forms “a,” “an,” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

When an element or layer is referred to as being “on,” “engaged to,” “connected to,” or “coupled to” another element or layer, it may be directly on, engaged, connected or coupled to the other element or layer, or intervening elements or layers may be present. In contrast, when an element is referred to as being “directly on,” “directly engaged to,” “directly connected to,” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the example embodiments.

Spatially relative terms, such as “inner,” “outer,” “beneath,” “below,” “lower,” “above,” “upper,” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

When the term “same” or “identical” is used in the description of example embodiments, it should be understood that some imprecisions may exist. Thus, when one element or value is referred to as being the same as another element or value, it should be understood that the element or value is the same as the other element or value within a manufacturing or operational tolerance range (e.g., ±10%).

When the terms “about” or “substantially” are used in connection with a numerical value, it should be understood that the associated numerical value includes a manufacturing or operational tolerance (e.g., ±10%) around the stated numerical value. Moreover, when the words “generally” and “substantially” are used in connection with a geometric shape, it should be understood that the precision of the geometric shape is not required but that latitude for the shape is within the scope of the disclosure.

Unless otherwise defined, all terms (including technical and scientific terms) used herein have the same meaning as commonly understood by one of ordinary skill in the art to which example embodiments belong. It will be further understood that terms, including those defined in commonly used dictionaries, should be interpreted as having a meaning that is consistent with their meaning in the context of the relevant art and will not be interpreted in an idealized or overly formal sense unless expressly so defined herein.

### DETAILED DESCRIPTION

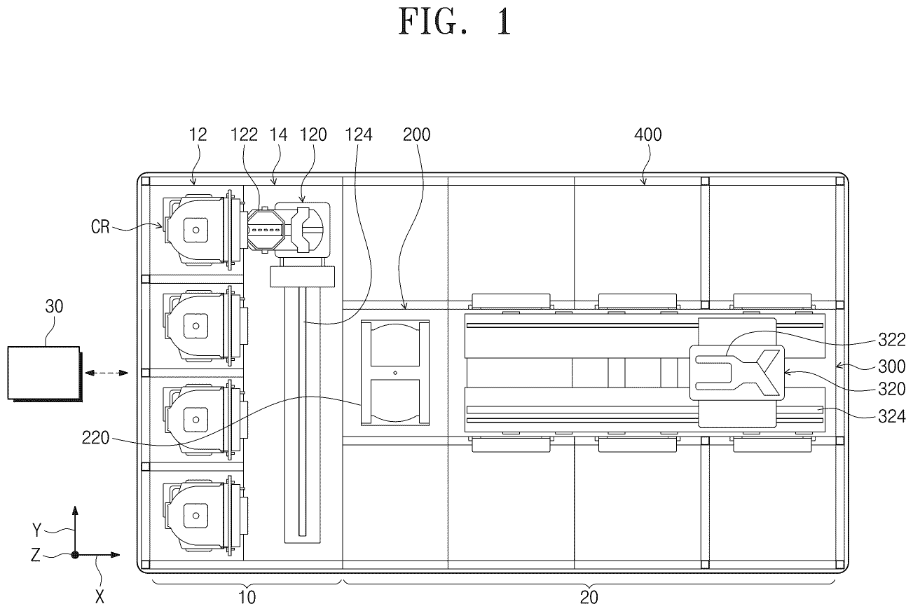

Hereinafter, an exemplary embodiment of the present invention will be described with reference to FIGS. 1 to 22.

FIG. 1 is a top plan view schematically illustrating a substrate processing apparatus according to an exemplary embodiment of the present invention.

Referring to FIG. 1, a substrate processing apparatus includes an index module 10, a processing module 20, and a controller 30. When viewed from above, the index module 10 and the processing module 20 are disposed along one direction. Hereinafter, the direction in which the index module 10 and the processing module 20 are disposed is referred to as a first direction X, and when viewed from above, a direction perpendicular to the first direction X is referred to as a second direction Y, and a direction perpendicular to both the first direction X and the second direction Y is referred to as a third direction Z.

The index module 10 transfers a substrate M from a container CR in which the substrate M is accommodated to the processing module 20, and makes the substrate M, which has been completely processed in the processing module 20, be accommodated in the container CR. A longitudinal direction of the index module 10 is provided in the second direction Y. The index module 10 includes a load port 12 and an index frame 14. Based on the index frame 14, the load port 12 is located at a side opposite to the processing module 20. The containers CR in which the substrates Mare accommodated are placed on the load ports 12. The load port 12 may be provided in plurality, and the plurality of load ports 12 may be disposed in the second direction Y.

As the container CR, an airtight container, such as a Front Open Unified Pod (FOUP), may be used. The container CR may be placed on the load port 12 by a transfer means (not illustrated), such as an overhead transfer, an overhead conveyor, or an automatic guided vehicle, or an operator.

An index robot 120 is provided to the index frame 14. A guide rail 124 of which a longitudinal direction is the second direction Y is provided within the index frame 14, and the index robot 120 may be provided to be movable on the guide rail 124. The index robot 120 includes a hand 122 on which the substrate M is placed, and the hand 122 may be provided to be movable forward and backward, rotatable about the third direction Z, and movable along the third direction Z. The plurality of hands 122 is provided while being spaced apart from each other in the up and down direction, and is capable of independently moving forward and backward.

The controller 30 may control components of the substrate processing apparatus. The controller 30 may include a process controller formed of a microprocessor (computer) that executes the control of the substrate processing apparatus, a user interface formed of a keyboard in which an operator performs a command input operation or the like in order to manage the substrate processing apparatus, a display for visualizing and displaying an operation situation of the substrate processing apparatus, and the like, and a storage unit storing a control program for executing the process executed in the substrate processing apparatus under the control of the process controller or a program, that is, a processing recipe, for executing the process in each component according to various data and processing conditions. Further, the user interface and the storage unit may be connected to the process controller. The processing recipe may be stored in a storage medium in the storage unit, and the storage medium may be a hard disk, and may also be a portable disk, such as a CD-ROM or a DVD, or a semiconductor memory, such as a flash memory.

The controller 30 may control the substrate processing apparatus to perform the substrate processing method described below. For example, the controller 30 may control the components provided to a liquid processing chamber 400 so as to perform the substrate processing method described below.

The processing module 20 includes a buffer unit 200, a transfer chamber 300, and a liquid processing chamber 400. The buffer unit 200 provides a space in which the substrate M loaded into the processing module 20 and the substrate M unloaded from the processing module 20 stay temporarily. The liquid processing chamber 400 performs a processing process of liquid-processing the substrate M by supplying a liquid onto the substrate W. The transfer chamber 300 transfers the substrate M between the buffer unit 200 and the liquid processing chamber 400.

The transfer chamber 300 may be provided so that a longitudinal direction is the first direction X. The buffer unit 200 may be disposed between the index module 10 and the transfer chamber 300. The liquid processing chamber 400 may be disposed on a side portion of the transfer chamber 300. The liquid processing chamber 400 and the transfer chamber 300 may be disposed in the second direction Y. The buffer unit 200 may be located at one end of the transfer chamber 300.

According to the example, the liquid processing chambers 400 are respectively disposed on opposite sides of the transfer chamber 300. At one side of the transfer chamber 300, the liquid processing chambers 400 may be provided in an array of A×B (each of A and B is 1 or a natural number larger than 1) in the first direction X and the third direction Z.

The transfer chamber 300 includes a transfer robot 320. A guide rail 324 having a longitudinal direction in the first direction X is provided in the transfer chamber 300, and the transfer robot 320 may be provided to be movable on the guide rail 324. The transfer robot 320 includes a hand 322 on which the substrate M is placed, and the hand 322 may be provided to be movable forward and backward, rotatable about the third direction Z, and movable along the third direction Z. A plurality of hands 322 are provided to be spaced apart in the vertical direction, and the hands 322 may move forward and backward independently of each other.

The buffer unit 200 includes a plurality of buffers 220 on which the substrate M is placed. The buffers 220 may be disposed while being spaced apart from each other in the third direction Z. A front face and a rear face of the buffer unit 200 are opened. The front face is a face facing the index module 10, and the rear face is a face facing the transfer chamber 300. The index robot 120 may approach the buffer unit 200 through the front face, and the transfer robot 320 may approach the buffer unit 200 through the rear face.

Hereinafter, the substrate M processed in the liquid processing chamber 400 will be described in detail.

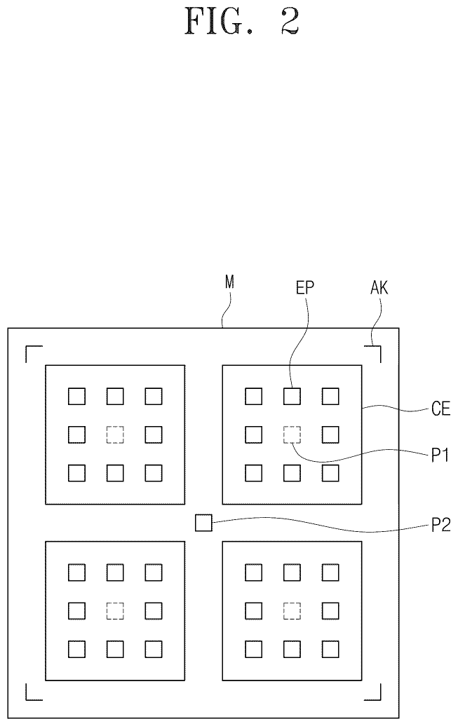

FIG. 2 is a diagram schematically illustrating a state of a substrate processed in the liquid processing chamber of FIG. 1.

Referring to FIG. 2, an object to be processed in the liquid processing chamber 400 may be a substrate of any one of a wafer, a glass, and a photomask. Hereinafter, a case where the substrate M processed in the liquid processing chamber 400 is a photo mask which is a “frame” used in the exposure process will be described as an example.

The substrate M may have a rectangular shape. The substrate M may be a photomask which is a ‘frame’ used in an exposure process. At least one reference mark AK may be marked on the substrate M. For example, a plurality of reference marks AK may be formed on corner areas of the substrate M, respectively. The reference mark AK may be a mark used when aligning the substrate M, which is called an alignment key. Also, the reference mark AK may be a mark used for deriving position information of the substrate M. For example, a vision sensor (not illustrated), such as a camera, may be provided in the liquid processing chamber 400, and the vision sensor may acquire an image by photographing the reference mark AK, and the controller 30 may detect the position and direction of the substrate M by analyzing the image including the reference mark AK. Also, the reference mark AK may be used for determining the position of the substrate M when the substrate M is transferred.

A cell CE may be formed on the substrate M. At least one cell CE, for example, a plurality of cells CE, may be formed. A plurality of patterns may be formed in each cell CE. The patterns formed in each cell CE may be defined as one pattern group. The pattern formed in the cell CE may include an exposure pattern EP and a first pattern P1. The exposure pattern EP may be used to form an actual pattern on the substrate M. Also, the first pattern P1 may be a pattern representing the exposure patterns EPs formed in one cell CE. Also, a plurality of first patterns P1 may be formed in one cell CE. The first pattern P1 may have a shape obtained by combining portions of the respective exposure patterns EPs. The first pattern P1 may be referred to as a monitoring pattern. Also, the first pattern P1 may be referred to as a critical dimension monitoring macro.

When an operator inspects the first pattern P1 through a Scanning Electron Microscope (SEM), it is possible to estimate whether the shapes of the exposure patterns EPs formed in one cell CE are good or poor. Also, the first pattern P1 may be an inspection pattern. Also, the first pattern P1 may be any one of the exposure patterns EPs participating in the actual exposure process. Also, the first pattern P1 may be an inspection pattern and may be an exposure pattern participating in actual exposure.

The second pattern P2 may be a pattern representing the exposure patterns EPs formed on the entire substrate M. For example, the second pattern P2 may have a shape obtained by combining portions of the respective first patterns P1.

When an operator inspects the second pattern P2 through a Scanning Electron Microscope (SEM), it is possible to estimate whether the shapes of the exposure patterns EPs formed in one cell substrate M are good or poor. Also, the second pattern P2 may be an inspection pattern. Also, the second pattern P2 may be an inspection pattern that does not participate in an actual exposure process. The second pattern P2 may be referred to as an anchor pattern.

Hereinafter, a substrate processing apparatus provided to the liquid processing chamber 400 will be described in detail. The liquid processing chamber 400 performs a predetermined process on the substrate M. More specifically, the process performed in the process chamber 400 may be a fine critical dimension correction (FCC) process in the process of manufacturing a mask for an exposure process. The substrate M loaded into the liquid processing chamber 400 may require adjustment of the line width of at least one of the first pattern P1, the second pattern P2, and the exposure pattern EP. That is, the process chamber 400 may etch a specific pattern (e.g., the second pattern P2) among the plurality of patterns formed on the substrate M. In addition, the substrate M processed in the process chamber 400 may be the substrate M on which the pre-processing has been performed.

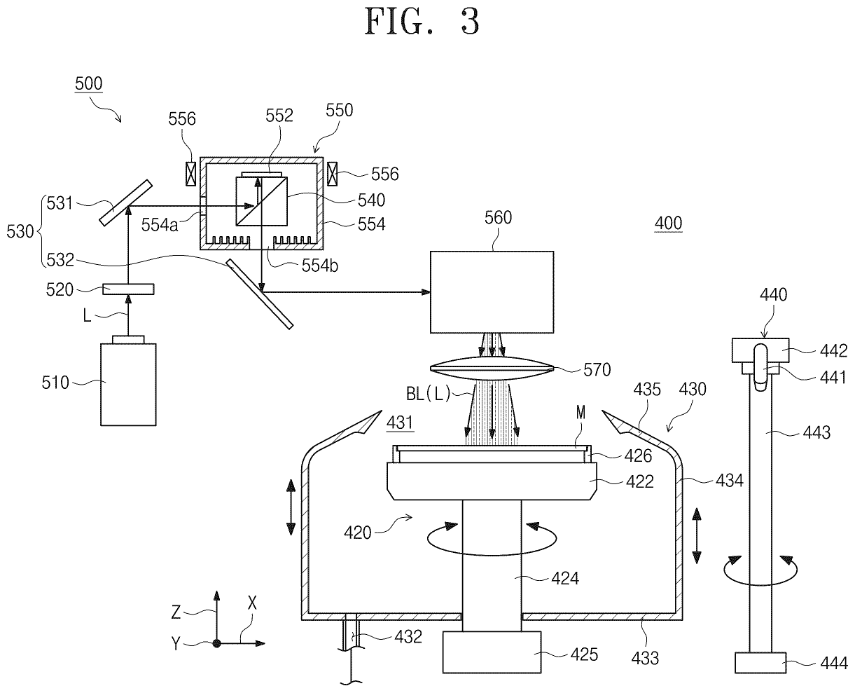

FIG. 3 is a diagram schematically illustrating an exemplary embodiment of the liquid processing chamber of FIG. 1. Referring to FIG. 3, the liquid processing chamber 400 includes a support unit 420, a bowl 430, a chemical liquid supply unit 440, and a laser irradiation unit 500.

The support unit 420 may support the substrate M in the processing space 431 defined by the bowl 430 which will be described later. The support unit 420 may support the substrate M. The support unit 420 may rotate the substrate M.

The support unit 420 may include a chuck 422, a support shaft 424, a driving member 425, and a support pin 426. The support pin 426 may be installed at the chuck 422. The chuck 422 may have a plate shape having a predetermined thickness. The support shaft 424 may be coupled to a lower portion of the chuck 422. The support shaft 424 may be a hollow shaft. Also, the support shaft 424 may be rotated by the driving member 425. The driving member 425 may be a hollow motor. When the driving member 425 rotates the support shaft 424, the chuck 422 coupled to the support shaft 424 may be rotated. The substrate M placed on the support pin 426 installed at the chuck 422 may also be rotated along with the rotation of the chuck 422.

The support pin 426 may support the substrate M. When viewed from the top, the support pin 426 may have a substantially circular shape. Also, when viewed from the top, the support pin 426 may have a shape in which a portion corresponding to the edge area of the substrate M is indented downward. That is, the support pin 426 may include a first surface supporting a lower portion of the edge area of the substrate M, and a second surface facing a side portion of the edge area of the substrate M so as to limit a movement of the substrate M in the lateral direction when the substrate M is rotated. At least one support pin 426 may be provided. A plurality of support pins 426 may be provided. The support pin 426 may be provided in the number corresponding to the number of corner areas of the substrate M having a rectangular shape. The support pin 426 may support the substrate M to separate a lower surface of the substrate M from an upper surface of the chuck 422.

The bowl 430 may have a cylindrical shape with an open top. The bowl 430 may define the processing space 431. The substrate M may be subjected to liquid processing and heat processing in the processing space 431. The bowl 430 may prevent the processing liquid supplied to the substrate M from being scattered and delivered to the chemical liquid supply unit 440 and the laser irradiation unit 500.

The bowl 430 may have a bottom portion 433, a vertical portion 434, and an inclined portion 435. When viewed from the top, an opening into which the support shaft 424 may be inserted may be formed in the bottom portion 433. The vertical portion 434 may extend from the bottom portion 433 in the third direction Z. The inclined portion 435 may extend obliquely upward from the vertical portion 434. For example, the inclined portion 435 may extend obliquely in a direction toward the substrate M supported by the support unit 420. The bottom portion 433 may be formed with a discharge hole 432 through which the processing liquid supplied by the chemical liquid supply unit 440 may be discharged to the outside.

Also, the bowl 430 may be coupled to a lifting member (not illustrated), and the position of the bowl 430 may be changed along the third direction Z. The lifting member may be a driving device that moves the bowl 430 in the up and down direction. The lifting member may move the bowl 430 upward while the liquid processing and/or the heat processing is performed on the substrate M, and may move the bowl 430 downward when the substrate M is loaded into the liquid processing chamber 400 or the substrate M is unloaded from the liquid processing chamber 400.

The chemical liquid supply unit 440 may supply a chemical liquid for liquid-processing the substrate M. The chemical liquid supply unit 440 may supply the chemical liquid to the substrate M supported by the support unit 420. The chemical liquid may be an etching liquid or a rinse liquid. The etching solution may be chemical. The etching liquid may etch a pattern formed on the substrate M. The etching liquid may be called an etchant. The rinse liquid may clean the substrate M. The rinse liquid may be provided as a known chemical solution.

The chemical liquid supply unit 440 may include a nozzle 441, a fixing body 442, a rotary shaft 443, and a rotary member 444.

The nozzle 441 may supply the processing liquid to the substrate M supported by the support unit 420. One end of the nozzle 441 may be connected to the fixing body 442, and the other end thereof may extend in a direction from the fixing body 442 toward the substrate M. The nozzle 441 may extend from the fixing body 442 in the first direction X. Further, the other end of the nozzle 441 may be bent at a predetermined angle and extend in a direction toward the substrate M supported by the support unit 420.

If necessary, a plurality of nozzles 441 may be provided. One of the nozzles 441 may be a nozzle for discharging the etchant, and the other of the nozzles 441 may be a nozzle for discharging the rinse liquid.

The body 442 may fix and support the nozzle 441. The body 442 may be connected to the rotary shaft 443 that is rotated in the third direction Z by the rotary member 444. When the rotary member 444 rotates the rotary shaft 443, the body 442 may be rotated in the third direction Z. Accordingly, a discharge port of the nozzle 441 may be moved between a liquid supply position, which is a position for supplying the processing liquid to the substrate M, and a standby position, which is a position for not supplying the processing liquid to the substrate M.

The laser irradiation unit 500 may irradiate the substrate M with a laser. The laser irradiation unit 500 may adjust the line width of the pattern formed on the substrate M by irradiating the substrate M having a liquid film formed on the upper surface thereof with a laser by a chemical solution (e.g., an etchant) supplied by the chemical solution supply unit 440. The temperature of the area of the substrate M irradiated with the laser irradiated by the laser irradiation unit 500 may increase. Accordingly, etching may be relatively further performed in the area which is irradiated with the laser, and etching may be relatively less performed in the area which is not irradiated with the laser. In this way, the line width of the pattern formed on the substrate M may be adjusted.

The laser irradiation unit 500 may irradiate a laser beam to the substrate M, which is a mask. The laser irradiation unit 500 may adjust the line width of the pattern formed on the substrate M by irradiating the substrate M having a liquid film formed on the upper surface thereof with light by a chemical solution (e.g., an etchant) supplied by the chemical solution supply unit 440. The temperature of the area of the substrate M irradiated with the light irradiated by the laser irradiation unit 500 may increase. Accordingly, etching may be relatively further performed in the area which is irradiated with the light, and etching may be relatively less performed in the area which is not irradiated with the light. In this way, the line width of the pattern formed on the substrate M may be adjusted.

The laser irradiation unit 500 may include a laser source 510, a flat top optical instrument 520, a mirror 530, an optical instrument 540, an optical modulation unit 550, an optical dumper 554, a cooling device 556, an irradiation position change instrument 560, and a lens 570.

The laser source 510 may generate a laser beam L. The laser source 510 may generate a laser beam L having linearity. The laser source 510 may generate a laser beam. The laser source 510 may be referred to as a laser beam source. The laser beam L generated by the laser source 510 may be irradiated to the substrate M to heat the substrate M. The laser source 510 may generate the laser beam L with an output capable of properly driving the optical modulation unit 550 without damage.

The flat top optical instrument 520 may convert a shape of light output from the laser source 510.

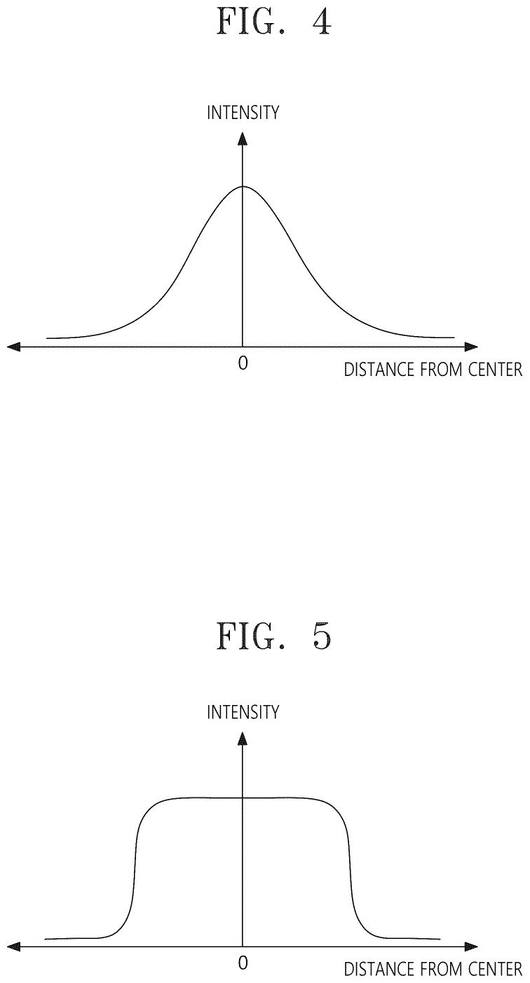

FIG. 4 is a graph illustrating distribution of light output from the laser source, and FIG. 5 is a graph illustrating distribution of light passing through the flat top optical instrument.

Referring to FIGS. 3 to 5, the laser beam output from the laser source 510 may have a Gaussian form in which an intensity distribution has the Gaussian distribution as illustrated in FIG. 4. More specifically, the intensity of the laser beam output from the laser source 510 is greater at the center of the laser beam, and the intensity thereof may gradually decrease as the laser beam moves away from the center of the laser beam (see FIG. 4). Accordingly, when the substrate M is irradiated with the laser beam output from the laser source 510, an area close to the center of the laser beam L may be further heated, and an area close to the edge of the laser beam may be less heated. Accordingly, when the laser beam L is transmitted to the optical modulation element 552 to be described later, light is transmitted to a portion of the optical modulation element 552 corresponding to the center portion of the laser beam L more than necessary, thereby causing damage to the optical modulation element 552, while light is not sufficiently transmitted to a portion of the optical modulation element 552 corresponding to the edge of the laser beam L, and thus the optical modulation efficiency of the optical modulation element 552 may be reduced.

Accordingly, in the laser irradiation unit 500 according to the exemplary embodiment of the present invention, the flat top optical instrument 520 may be disposed on the traveling path of the laser beam L output from the laser source 510. The flat top optical mechanism 520 may be a laser beam shaper that converts the Gaussian-formed laser beam L output from the laser source 510 into a flat top-formed laser beam L. The laser beam L output from the laser source 510 may be converted into a flat top form having a relatively uniform intensity (luminosity) distribution through the flat top optical instrument 520 (see FIG. 5). Since the laser beam L of the flat top form is modulated by the optical modulation element 552, utilization of the optical modulation element 552 and optical modulation efficiency may be improved.

Referring back to FIG. 3, the laser beam L passing through the flat top optical instrument 520 may be reflected by a first mirror 531 among the mirrors 530. Light reflected by the first mirror 531 may be transmitted to the optical instrument 540.

The optical instrument 540 may pass through the flat top optical instrument 520 and reflect the laser beam L reflected by the first mirror 531 again to the optical modulation unit 550. The optical mechanism 540 may be a prism or a mirror. The optical instrument 540 may be applied in various configurations capable of transmitting the laser beam L reflected by the first mirror 531 to the optical modulation unit 550. The laser beam L transmitted to the optical modulation unit 550 may be modulated by the optical modulation unit 550 and outputted. The laser beam L modulated and output by the optical modulation unit 550 may pass through the optical instrument 540 and be transmitted to the second mirror 532 among the mirrors 530. The laser beam L transmitted to the second mirror 532 may be reflected and transmitted to the irradiation position change instrument 560.

The optical modulation unit 550 may modulate the transmitted laser beam L. The optical modulation unit 550 may include the optical modulation element 552, the optical dumper 554, and the cooling device 556.

The optical modulation element 552 may modulate the shape and distribution of the laser beam L generated by the laser source 510. Here, modulating the shape and distribution of the laser beam L may be forming the shape and distribution of the laser beam L corresponding to the irradiation pattern of the laser beam L to be irradiated to the substrate M.

The optical modulation element 552 may be a Digital Micro-mirror Device (DMD).

That is, the optical modulation unit 550 may be a DMD unit including a DMD.

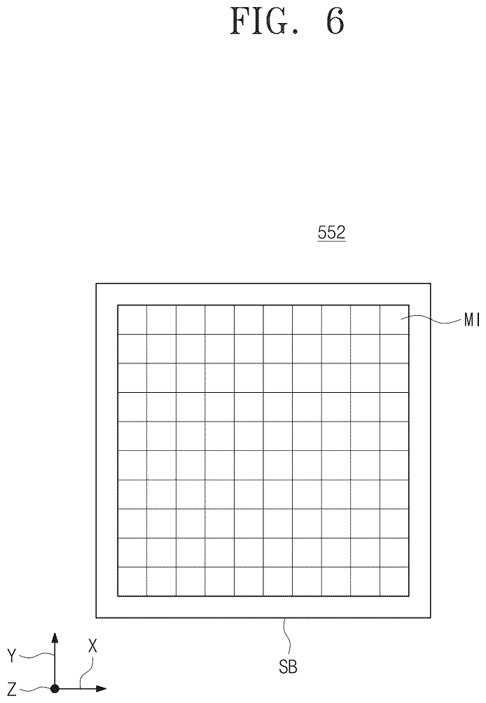

FIG. 6 is a diagram schematically illustrating the optical modulation element. The optical modulation element 552 may include a board substrate SB and a plurality of micromirrors MI. Electrodes respectively corresponding to the plurality of micromirrors MIs may be installed on the board substrate SB. The controller 30 may transmit a digital signal of “0” or “1” to an electrode installed on the board substrate SB. The micromirrors MIs may be rotatably configured. The micromirrors MIs may be rotatably configured with respect to the first direction X, the second direction Y, or a direction parallel to a plane passing through the first direction X and the second direction Y as a rotation axis. The micromirror MI corresponding to the electrode to which the digital signal of “O” has been transmitted may be in an off state, and the micromirror MI corresponding to the electrode to which the digital signal of “1” has been transmitted may be in an on state. The on-state micromirror MI may irradiate the substrate M with the laser beam L, and the substrate M may not be irradiated with the laser beam L reflected by the off-state micromirror MI.

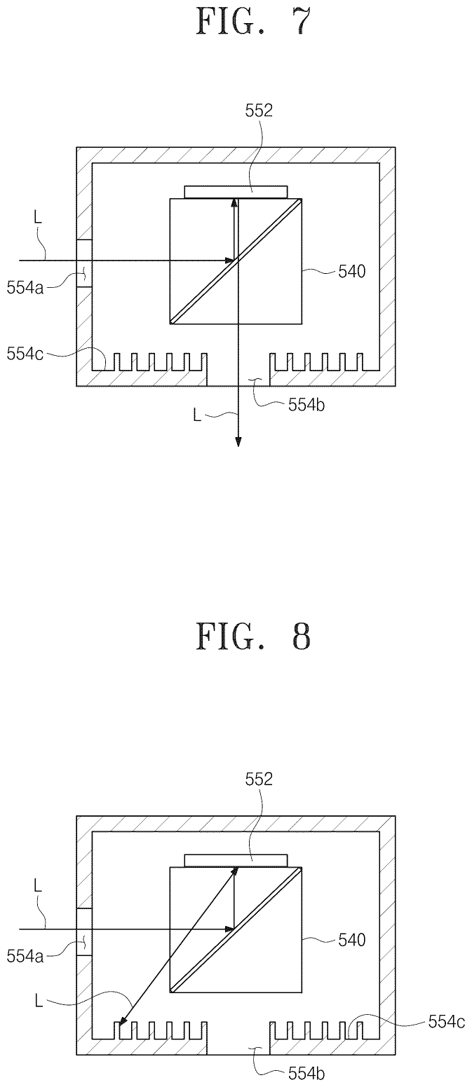

FIG. 7 is a diagram illustrating a state in which a laser beam is output from the optical modulation element. For convenience of description, FIG. 7 illustrates a traveling path of a laser beam L reflected by any one of the micromirrors MI. Referring to FIGS. 3, 6, and 7, the laser beam L reflected by the on-state micromirror MI may be output and transmitted to the substrate M.

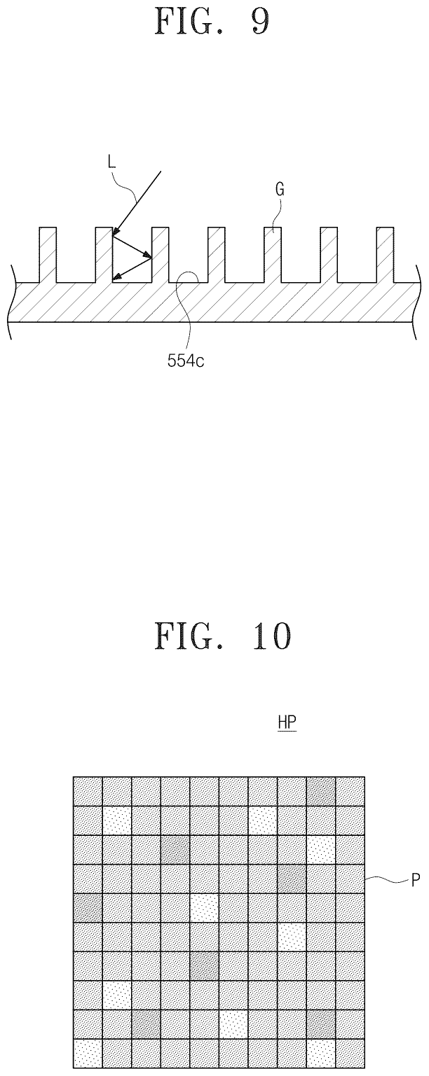

FIG. 8 is a diagram illustrating a state in which a laser beam output from the optical modulation element is removed from the optical dumper. For convenience of description, FIG. 8 illustrates a traveling path of a laser beam L reflected by any one of the micromirrors MI. Referring to FIGS. 3, 6, and 8, the micromirror MI that is in the off state may reflect the laser beam L and may not transmit the laser beam L to the substrate M. Specifically, the micromirror MI is configured to be rotatable as described above. The off-state micromirror MI may rotate to change a traveling path of the laser beam L transmitted from the laser source 510 so that light is not transmitted to the substrate M. The laser beam L emitted from the off-state micromirror MI may not pass through a second hole 554b of the optical dumper 554 to be described later and may irradiate the inner surface of the optical dumper 554 to be extinguished. That is, the micromirror in the off-state may dump the laser beam L.

FIG. 9 is a diagram for describing a principle in which a laser beam is removed from the optical dumper. Referring to FIGS. 3 and 9, the optical dumper 554 may have a cylindrical shape having an inner space. The optical dumper 554 may be made of a material, such as synthetic resin, that may absorb and remove the laser beam L. The optical instrument 540 may be disposed in the inner space of the optical dumper 554. The optical modulation element 552 may be disposed in the inner space of the optical dumper 554 or may be installed outside the optical dumper 554.

The optical dumper 554 may be formed with a first hole 554a and a second hole 554b. The first hole 554a may be formed on a side portion of the optical dumper 554. The first hole 554a may be a hole through which the laser beam L generated by the laser source 510 and converted through the flat top optical instrument 520 passes. The second hole 554b may be a hole through which the laser beam L modulated by the optical modulation element 552 passes. The second hole 554b may be formed under the optical dumper 554.

A groove G may be formed on an inner side surface 554c of the optical dumper 554. The groove G formed on the inner side surface 554c of the optical dumper 554 may be configured to absorb light reflected by the off-state micromirror MI. Specifically, when the laser beam L is transmitted to the groove G, the laser beam L may be removed while being reflected in the groove G several times. The laser beam L may be removed while being reflected several times in the groove G and losing thermal energy to the optical dumper 554. Although FIG. 3 and FIG. 9 illustrate that the groove G is formed only in the lower portion of the optical dumper 554, the present invention is not limited thereto, and the groove G may be formed over the entire inner surface 554c of the optical dumper 554.

Referring back to FIG. 3, as the optical dumper 554 removes the laser beam L, the temperature of the optical dumper 554 may increase. Accordingly, the laser irradiation unit 500 according to the exemplary embodiment of the present invention may include the cooling device 556 for cooling the optical dumper 554. The cooling mechanism 556 may be a fan forming an airflow for cooling the optical dumper 554.

FIG. 10 is a diagram for describing an irradiation pattern of a laser beam output from the optical modulation element. Referring to FIGS. 3, 6, and 10, as described above, the micromirror MI may be switched between an on-state and an off-state. Each of the micromirrors MIs may selectively switch between the on-state that reflects the laser beam L so that the laser beam L irradiates the substrate M and the off-state that dumps the laser beam L by adjusting a direction in which each of the micromirrors MIs reflects the laser beam L. Each of the micromirrors MIs may control the time during which the laser beam L irradiates the substrate M by controlling the time during which each of the micromirrors MIs maintains the on-state and the off-state.

Switching between the on-state and the off-state of each micromirror MI may be performed within a very short time. According to the switching between the on state and the off state of each micromirror MI, the optical modulation unit 550 may form a wide variety of irradiation patterns HPs.

For example, FIG. 10 illustrates the amount of heat transferred to the substrate M by the laser beam L reflected from each micromirror MI for a unit time (e.g., 1 second) per unit time. The irradiation pattern HP may include a plurality of patterns P corresponding to the micromirrors MIs, respectively. In order to increase the amount of heat transferred to the substrate M per unit time in each micromirror MI, the on-state of the micromirror MI per unit time may be maintained long and the off-state may be maintained short. In order to reduce the amount of heat transferred to the substrate M per unit time in each micromirror MI, the on-state of the micromirror MI per unit time may be maintained short and the off-state may be maintained long.

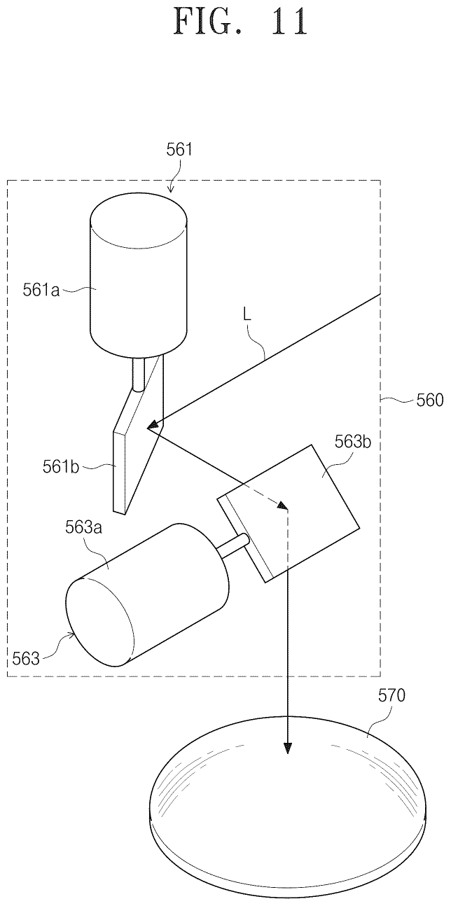

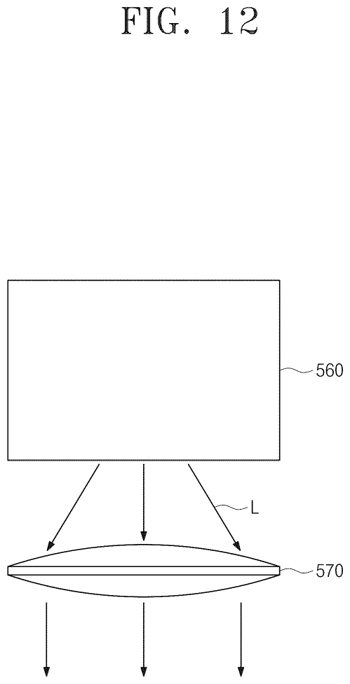

FIG. 11 is a view illustrating a state in which an irradiation position change instrument changes an irradiation position of the laser beam. Referring to FIGS. 3 and 11, the irradiation position change instrument 560 may reflect the laser beam L which has been modulated by the optical modulation unit 550 and has a specific irradiation pattern HP and change the irradiation position. The irradiation position change instrument 560 may be installed in the liquid processing chamber 400 with a fixed position. The irradiation position change instrument 560 may include a first reflection instrument 561 and a second reflection instrument 563. The first reflection instrument 561 may include a first rotation driver 561a and a first rotation mirror 561b. The second reflection mechanism 563 may include a second rotation driver 563a and a second rotation mirror 563b. The first rotation driver 561a and the second rotation driver 563a may be motors. The laser beam L modulated by the optical modulation unit 550 may be reflected by the first reflection mechanism 561 and transmitted to the second reflection mechanism 563. The laser beam L transmitted to the second reflection mechanism 563 may be reflected again by the second reflection mechanism 563 and transmitted to the lens 570. The irradiation position change instrument 560 may be a Galvano scanner.

A rotation axis of the first rotation mirror 561b and a rotation axis of the second rotation mirror 563b may not be parallel to each other. Also, the rotation axis of the first rotation mirror 561b and the rotation axis of the second rotation mirror 563b may not be perpendicular as necessary. Accordingly, the irradiation position of the laser beam L reflected and transmitted through the second mirror 532 may be variously changed by the rotation of the first rotation mirror 561b and the second rotation mirror 563b.

FIG. 12 is a diagram illustrating a state in which irradiation position change instrument switches a traveling direction of a laser beam traveling in an oblique direction to a vertical direction. Referring to FIGS. 3 and 12, the laser beam L of which the irradiation position is changed in the irradiation position change instrument 560 may travel in an inclined direction. When the laser beam L traveling in the inclined direction is directly transmitted to the substrate M by the irradiation position change instrument 560, the laser beam L may be obliquely incident on the substrate M. To solve this problem, in the laser irradiation unit 500 according to the exemplary embodiment of the present invention, a lens 570 may be disposed between the irradiation position change instrument 560 and the support unit 420. The lens 570 may be an F-Theta lens. The lens 570 may be configured to refract light that travels obliquely with respect to the third direction Z that is vertical to the ground in the third direction Z, which is a vertical direction, by the irradiation position change instrument 560.

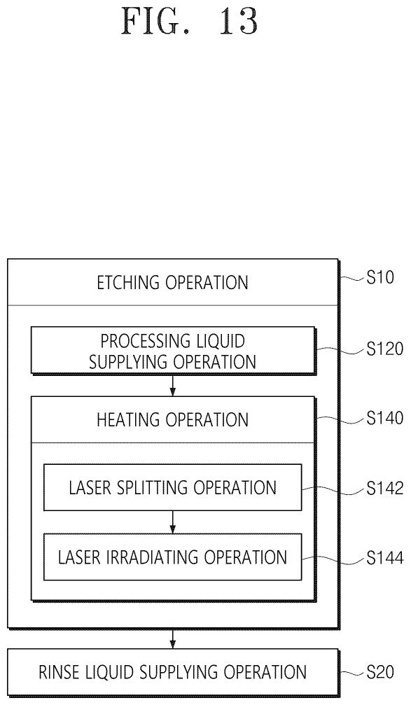

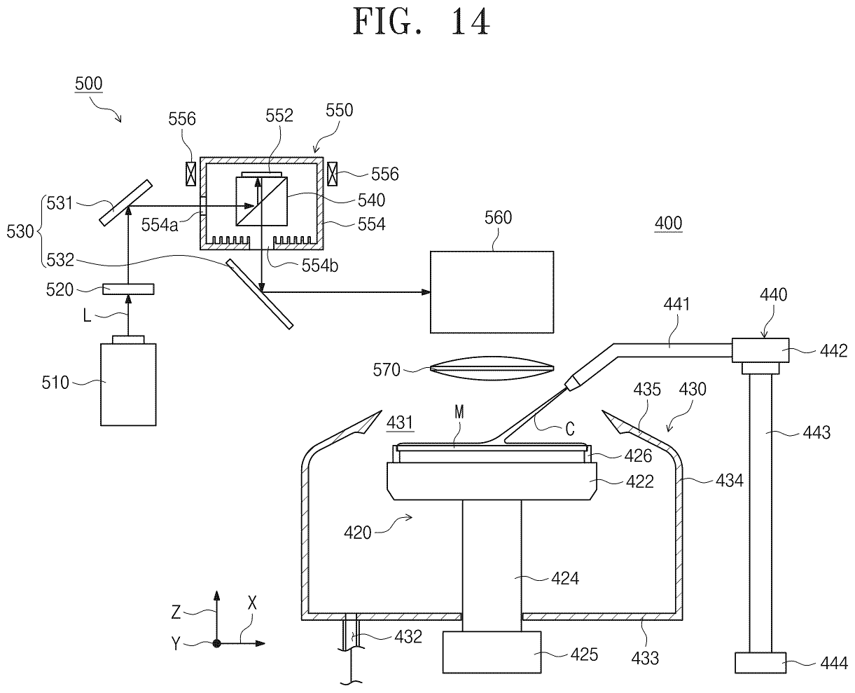

FIG. 13 is a flowchart illustrating a substrate processing method according to an exemplary embodiment of the present invention. Hereinafter, a substrate processing method according to an exemplary embodiment of the present invention will be described with reference to FIGS. 12 to 22. The substrate processing method according to the exemplary embodiment of the present invention may be a mask processing method for processing a mask. The substrate processing method described below may be performed by controlling, by the above-described controller 30, components included in the substrate processing apparatus. The substrate processing method described below may be performed in the substrate processing apparatus described above.

Referring to FIGS. 2, 3, and 13, the substrate processing method according to the exemplary embodiment of the present invention may include an etching operation S10 and a rinse liquid supplying operation S20. The etching operation S10 and the rinse liquid supplying operation S20 may be performed in order of time series.

The process of processing the substrate M in the etching operation S10 may be the above-described FCC. The etching operation S10 etches a specific area of the substrate M. More specifically, the etching operation S10 may etch an area in which the second pattern P2 is formed between the first pattern P1 and the second pattern P2 formed on the substrate M.

The etching operation S10 may include a processing liquid supplying operation S120 and a heating operation S140. The processing liquid supplying operation S120 and the heating operation S140 may be sequentially performed.

FIG. 14 is a cross-sectional view illustrating the substrate processing apparatus performing the processing liquid supplying operation according to the exemplary embodiment. As illustrated in FIG. 14, in the processing liquid supplying operation S120, the processing liquid C is supplied onto the substrate M. According to the exemplary embodiment, in the processing liquid supplying operation S120, the processing liquid C may be supplied while rotating the substrate M, and unlike this, the processing liquid C may be supplied without rotating the substrate M. The processing liquid C supplied in the processing liquid supplying operation S120 may be an etchant. The processing liquid C may be referred to as an etchant. When the processing liquid supplying operation S120 is terminated, a liquid film may be formed on the substrate M by the processing liquid C. In the processing liquid supplying operation S120, the support unit 420 may rotate the substrate M, or the support unit 420 may support the substrate M without rotating the substrate M so as to prevent the alignment of the substrate M from being distorted. When the processing liquid C is supplied to the substrate M of which rotation is stopped, the processing liquid C may be supplied in an amount sufficient to form a liquid film or a puddle.

For example, the amount of processing liquid C supplied to the substrate M may cover the entire upper surface of the substrate M, but may be supplied such that the amount of the processing liquid C does not flow from the substrate M or the amount of processing liquid C flowing down is not large even if the processing liquid C flows down. If necessary, the processing liquid C may be supplied to the rotating substrate M, or the processing liquid C may be supplied to the entire upper surface of the substrate M while changing the position of the nozzle 441 to form a liquid film or a puddle on the substrate M.

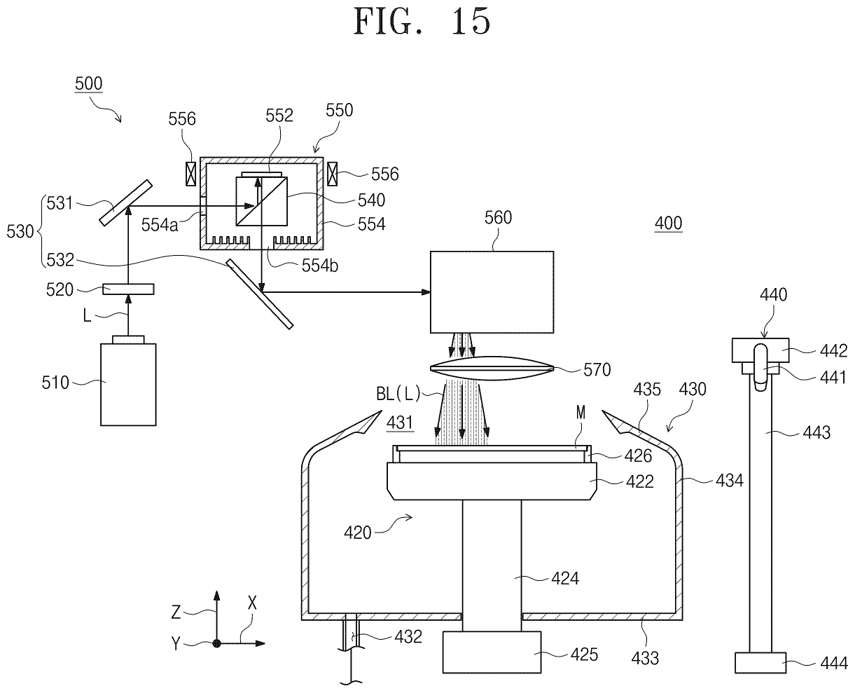

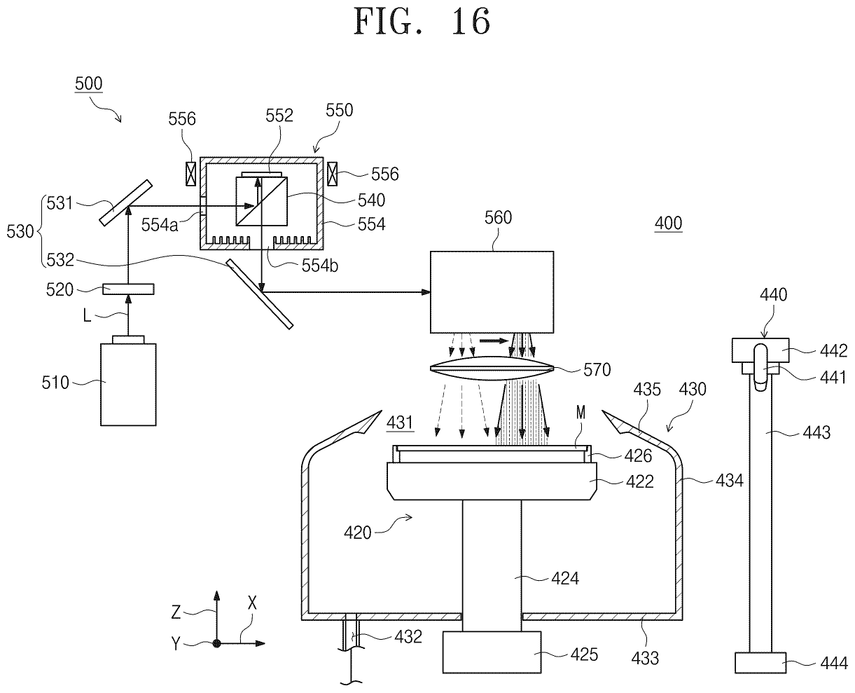

FIGS. 15 to 16 are cross-sectional views illustrating the substrate processing apparatus performing the heating operation according to the exemplary embodiment. As illustrated in FIG. 15, in the heating operation S140, the laser beam L is emitted from the laser irradiation unit 500 to heat the substrate M. More specifically, the laser irradiation unit 500 emits the laser beam L to a specific area (e.g., an area where the second pattern P2 is formed) of the substrate M on which the liquid film is formed. The laser irradiated to the substrate M may irradiate the specific area on the substrate M.

According to the exemplary embodiment, the heating operation S140 may include a laser splitting operation S142 and a laser irradiating operation S144.

In the laser splitting operation S142, the optical modulation unit 550 may modify the shape or distribution of the laser each or simultaneously by adjusting the on/off state of the micromirror MI described above. The laser beam L may be modulated so that the temperature profile of the laser irradiating the substrate M is uniformly present by deformation of the shape and distribution of the laser through the optical modulation unit 550. The optical modulation unit 550 may modulate the laser beam L and split the modulated laser beam L into a plurality of beamlets BLs. Each of the split beamlets BLs may be modulated so that the temperature profile of the laser irradiating the substrate M is uniform. Each of the split beamlets BLs may be irradiated to any one of a plurality of irradiation areas IA to be described later. This will be described later.

In the laser irradiating operation S144, the specific area of the substrate M may be heated by irradiating the upper surface of the substrate M on which the liquid film by the processing liquid C is formed with the laser beam L. The entire pattern on the substrate M is etched by the processing liquid C, but the specific area irradiated with the laser beam L may be heated to further be etched. The degree to which the substrate M is etched depends on the amount of heat transmitted by the laser beam L per unit time, and since the optical modulation unit 550 of the present invention may form various irradiation patterns having various shapes, the etching of the substrate M may be controlled in various forms. In the laser irradiating operation S144, the support unit 420 may support the substrate M without rotating the substrate M.

As illustrated in FIG. 16, the laser irradiation unit 500 may irradiate a specific area of the substrate M with the laser beam L, and then change the path of the laser beam L through the irradiation position change instrument 560 to irradiate a desired area of the substrate, that is, another area on the substrate M requiring heating, with the laser beam M.

When the heating operation S140 is terminated, the etching operation S10 is terminated, and the rinse liquid supplying operation S20 is performed.

FIG. 22 is a cross-sectional view illustrating the substrate processing apparatus performing a rinse liquid supplying operation according to the exemplary embodiment. In the rinse liquid supplying operation S20, the rinse liquid R is supplied to the substrate M. More specifically, in the rinse liquid supplying operation S20, the rinse liquid R may be supplied to the rotating substrate M. The rinse liquid R supplied to the substrate M removes etching impurities generated in the process of performing the etching operation S10 from the substrate M. Also, the rinse liquid R replaces the liquid film formed on the substrate M to clean the substrate M.

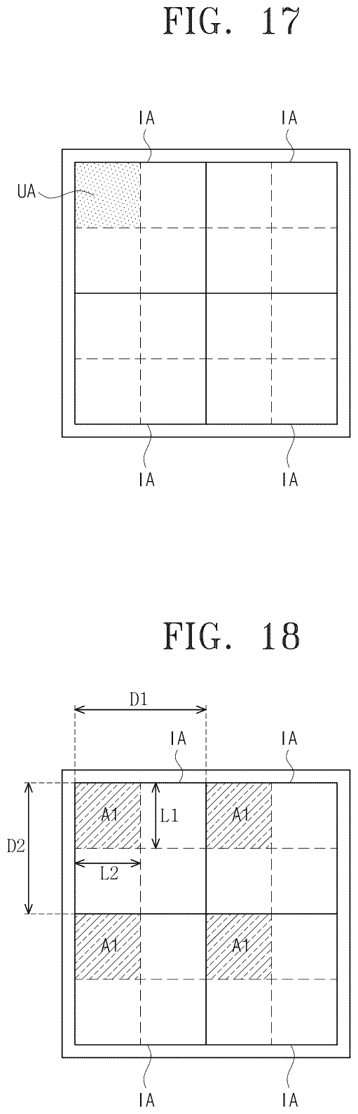

Hereinafter, the heating operation S140 according to the exemplary embodiment of the present invention will be described in more detail with reference to FIGS. 17 to 21.

FIG. 17 is a diagram schematically illustrating a configuration of a specific area which is irradiated with a laser beam. FIGS. 18 to 20 are diagrams illustrating a state in which the specific area of FIG. 17 is irradiated with a laser beam when the laser irradiating operation is performed.

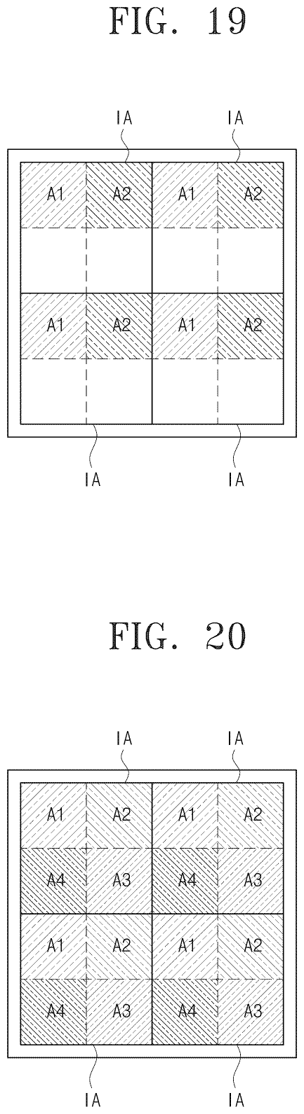

Referring to FIGS. 17 and 20, a specific area of the substrate M to be heated by being irradiated with the laser beam L may be split into a plurality of irradiation areas IA. A plurality of beamlets BLs split by the optical modulation unit 550 may be irradiated to the plurality of irradiation areas IAs, respectively. One irradiation area IA may correspond to one beamlet BL. The plurality of respective beamlets BLs is emitted in such a manner that they do not overlap or connect to one another.

The irradiation area IA may be divided into a plurality of unit irradiation areas UAs. For example, as illustrated in FIG. 20, each irradiation area IA may be divided into unit irradiation areas UAs exemplified by a first area A1, a second area A2, a third area A3, and a fourth area A4. Each of the unit irradiation areas UAs may be provided in a square shape. Any one of the plurality of beamlets BLs split by the optical modulation unit 550 may be sequentially emitted to the plurality of unit irradiation areas UAs in the corresponding irradiation area IA.

Referring to FIG. 18, each of the plurality of beamlets BLs split by the optical modulation unit 550 is emitted to the first area A1 among the unit irradiation areas UAs of the corresponding irradiation area IA.

A horizontal length L1 of the first area A1 may be 1/M of a horizontal length D1 of the irradiation area IA, and a vertical length L2 of the first area A1 may be 1/N of a vertical length D2 of the irradiation area IA. Each of M and N may be a natural number of 2 or more.

In this case, the area of the first area A1, that is, the area of the unit irradiation area UA, may be set to the area of the area where the irradiated area is uniformly heated when each beamlet BL split by the optical modulation unit 550 is emitted.

For example, when each beamlet BL modulated and split by the optical modulation unit 550 is capable of uniformly heating a 1 mm×1 mm area, that is, an area of 1 mm², the area of the unit irradiation area UA may be set freely within a maximum of 1 mm². The length of one side of the unit irradiation area UA may be a spatial resolution of a shape targeted as a minimum unit of etching.

When the area of the unit irradiation area UA is too large, a temperature gradient is formed inside the unit irradiation area UA when the beamlet BL is irradiated to the unit irradiation area UA, and when the area of the unit irradiation area UA is too small, the amount of heat transferred is insufficient and thus a desired heating amount may not be obtained, and thus the area of the unit irradiation area UA may be appropriately set at a level at which the irradiated area is uniformly heated.

When the beamlet BL heats the first area A1, the area of the first area A1 is set so that the indirect heating amount transferred to the second area A2 and the third area A3, which are adjacent areas, does not affect the heating and etching of the second area A2 and the third area A3. In other words, when one beamlet BL is irradiated to the first area A1, the adjacent second area A2 and third area A3 may not be affected by the beamlet BL. When one beamlet BL is irradiated to the unit irradiation area UA, the other adjacent unit irradiation area UA may be indirectly heated only to a level that does not affect heating or etching. Each unit irradiation area UA may maintain independence from heating of the adjacent unit irradiation area UA.

Referring to FIG. 19, the plurality of beamlets BLs split by the optical modulation unit 550 is emitted to the first area A1 among the unit irradiation areas UA of the corresponding irradiation area IA, and heats the first area A1, and then irradiates the second area A2 among the unit irradiation areas UAs of the corresponding irradiation area IA. The second area A2 may be an area adjacent to the first area A1. The area of the second area A2 may be the same as the area of the first area A1. In contrast, when each beamlet BL split by the optical modulation unit 550 is emitted, the area of the second area A2 may be freely set within a level that does not affect the adjacent unit irradiation area while the irradiated area is uniformly heated.

Referring to FIG. 20, the plurality of beamlets BLs split by the optical modulation unit 550 may be sequentially emitted to the first area A1, the second area A2, the third area A3, and the fourth area A4 among the unit irradiation areas UAs of the corresponding irradiation area IA to heat the entire irradiation area IA.

The widths of the first to fourth areas A1 to A4 are set so that the irradiated area is uniformly heated when the beamlet BL is emitted, respectively, but are set so that the beamlet BL does not affect the adjacent unit irradiation area UA when heating each unit irradiation area UA, so that it may be obtained the result that after the beamlets BLs sequentially heats the first to fourth areas A1 to A4, respectively, the cumulative heating amount may be uniform in the entire irradiation area IA.

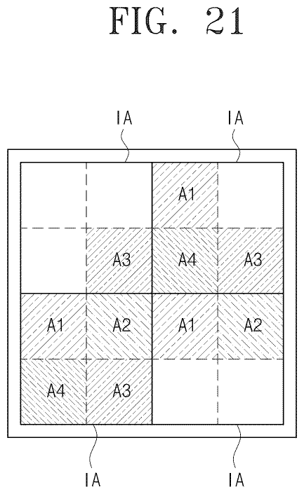

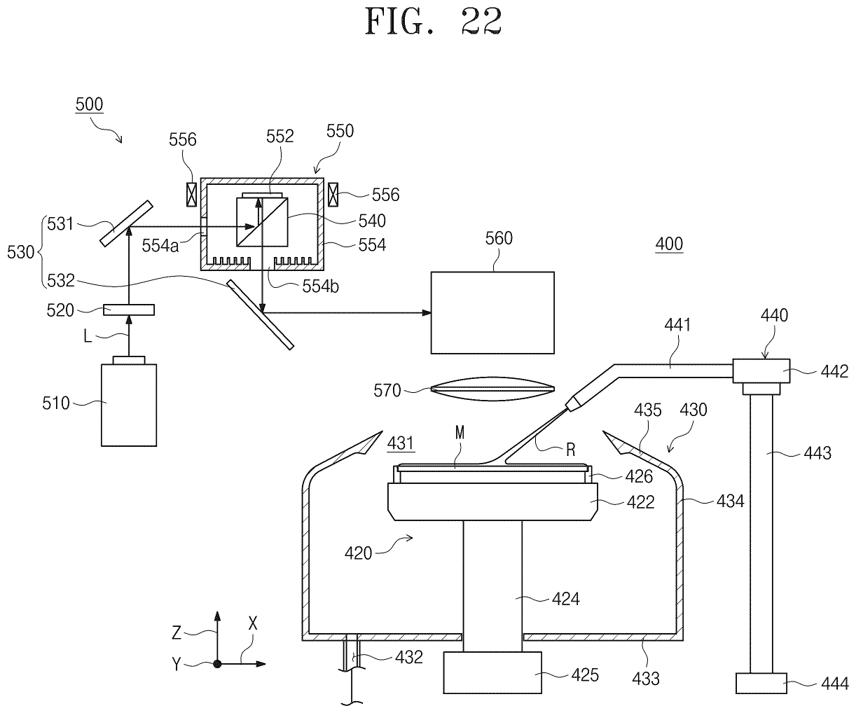

FIG. 21 is a diagram schematically illustrating an exemplary embodiment of irradiating and heating the substrate with a laser beam with respect to an arbitrary etching required shape. Referring to FIG. 21, an arbitrary etching required shape is divided into a plurality of irradiation areas IA, and as described in FIGS. 18 to 20, the plurality of beamlets BLs split by the optical modulation unit 550 is sequentially emitted to the unit irradiation areas UAs of the corresponding irradiation area IA, thereby uniformly heating the arbitrary etching required shape.

In the above-described exemplary embodiment, for convenience of description, it has been illustrated and described that the irradiation area IA is composed of four unit irradiation areas UA, but the present invention is not limited thereto. Depending on the material or thermal diffusion characteristics of the object which is irradiated with the laser beam L, the irradiation area IA may be composed of unit irradiation areas UAs having an array of M×N. Each of M and N may be a natural number of 2 or more.

In the above-described exemplary embodiment, for convenience of description, it has been illustrated and described that the unit irradiation area UA is configured in a square shape, but the present invention is not limited thereto. The unit irradiation area UA may be configured in a rectangle shape having different horizontal and vertical lengths. The unit irradiation area UA may be configured in a free shape within a level that does not affect adjacent unit irradiation areas while the irradiated area is uniformly heated. For example, the unit irradiation area UA is not limited to a rectangle and may be provided in a triangular or hexagonal shape.

In the present invention, the surface-shaped laser beam L is emitted through the optical modulation unit 550 rather than moving and emitting the laser beam L in the form of a point light source, so that the time for the substrate M to be exposed to the chemical solution may be reduced by shortening the irradiation time and the etching process efficiency of the substrate M may be increased.

According to the present invention, by splitting the laser beam L into a plurality of beamlets BLs and sequentially irradiating each unit irradiation area UA, uniform heating of the unit irradiation area UA may be promoted, and independence of each unit irradiation area UA may be secured. In addition, an arbitrary shape requiring heating may be uniformly heated simply by dividing and irradiating the unit irradiation area UA. According to the present invention, the substrate may be effectively etched by emitting the laser so that the temperature distribution within a specific area of the substrate requiring heating becomes uniform.

In the above exemplary embodiment, it has been described that one laser irradiation unit 500 irradiates a specific area of the substrate M with the laser beam L. However, unlike this, a plurality of laser irradiation units 500 may be provided, and each laser beam L may irradiate different areas of the substrate M.

In the above example, the present invention has been described based on the case where the substrate M processed in the liquid processing chamber 400 is a photo mask which is a “frame” used in an exposure process as an example, but the present invention is not limited thereto. For example, the substrate may be provided as various types and shapes of substrates requiring etching or adjustment of the pattern line width, such as a wafer, a glass substrate, and a metal film.

It should be understood that exemplary embodiments are disclosed herein and that other variations may be possible. Individual elements or features of a particular exemplary embodiment are not generally limited to the particular exemplary embodiment, but are interchangeable and may be used in selected exemplary embodiments, where applicable, even when not specifically illustrated or described. The modifications are not to be considered as departing from the spirit and scope of the present invention, and all such modifications that would be obvious to one of ordinary skill in the art are intended to be included within the scope of the accompanying claims.

1. A method of processing a substrate, the method comprising:
a heating operation of irradiating a substrate with a laser generated from a laser source and heating the substrate,
wherein the heating operation includes:
a laser splitting operation of splitting the laser into a plurality of beamlets using an optical modulation unit; and
a laser irradiating operation of irradiating the substrate with the plurality of beamlets, and
the plurality of beamlets is emitted so as not to overlap or be connected to one another.

2. The method of claim 1, wherein the substrate includes a plurality of irradiation areas that require heating, and
the optical modulation unit splits the laser so that the plurality of beamlets respectively irradiates the plurality of irradiation areas.

3. The method of claim 2, wherein the irradiation area is divided into a plurality of unit irradiation areas, and
the beamlet heats the entire irradiation area by sequentially irradiating the plurality of unit irradiation areas.

4. The method of claim 3, wherein when the beamlet heats the unit irradiation area, the unit irradiation area is heated uniformly.

5. The method of claim 3, wherein after the beamlet sequentially irradiates the plurality of unit irradiation areas to heat the entire irradiation area, a cumulative heating amount in the entire irradiation area is uniform.

6. The method of claim 3, wherein after a first area is heated by irradiating the first area among the plurality of unit irradiation areas with the beamlet,
a second area is heated by irradiating the second area among the plurality of unit irradiation areas with the beamlet, and
the second area is an area adjacent to the first area.

7. The method of claim 6, wherein a horizontal length of the first area is 1/M of a horizontal length of the irradiation area,
a vertical length of the first area is 1/N of a vertical length of the irradiation area, and
each of M and N is a natural number of 2 or more.

8. The method of claim 7, wherein an area of the second area is the same as an area of the first area.

9. The method of claim 3, wherein the unit irradiation area has a rectangular shape.

10. The method of claim 1, wherein the optical modulation unit is a Digital Micromirror Device (DMD) unit, and
the DMD unit includes:
micromirror provided rotatably; and
a board substrate on which the micromirrors are installed, and
the heating operation includes adjusting a direction in which each of the micromirrors reflects the laser, and selectively heating the substrate through switching between an on-state in which the laser is reflected to irradiate the substrate and an off-state, in which the laser is dumped.

11. The method of claim 1, further comprising:
a processing liquid supplying operation of supplying a processing liquid to the substrate prior to the heating operation.

12-15. (canceled)

16. A method of processing a substrate, the method comprising:
an etching operation of etching a substrate, wherein the etching operation of etching the substrate includes:
a processing liquid supplying operation of supplying a processing liquid to the substrate; and
a heating operation of irradiating the substrate with a laser generated from a laser source and heating the substrate,
wherein the heating operation includes:
a laser splitting operation of splitting the laser into a plurality of beamlets using a Digital Micromirror Device (DMD) unit including rotatably provided micromirrors; and
a laser irradiating operation of irradiating the substrate with the plurality of beamlets, and
the substrate includes a plurality of irradiation areas that require heating, and
each of the plurality of beamlets is emitted to correspond to one irradiation area.

17. The method of claim 16, wherein the irradiation area is divided into a plurality of unit irradiation areas, and
the beamlet heats the entire irradiation area by sequentially irradiating the plurality of unit irradiation areas.

18. The method of claim 17, wherein when the beamlet heats the unit irradiation area, the unit irradiation area is heated uniformly.

19. The method of claim 17, wherein after the beamlet sequentially irradiates the plurality of unit irradiation areas to heat the entire irradiation area, a cumulative heating amount in the entire irradiation area is uniform.

20. The method of claim 17, wherein after a first area is heated by irradiating the first area among the plurality of unit irradiation areas with the beamlet,
a second area is heated by irradiating the second area among the plurality of unit irradiation areas with the beamlet, and
the second area is an area adjacent to the first area, and
the first area and the second area have a rectangular shape.
